(19) United States
(12) Patent Application Publication
(10) Pub. No.: US 2016/0019965 A1
(43) Pub. Date: Jan. 21, 2016

(54) SEMICONDUCTOR MEMORY DEVICE

(71) Applicant: KABUSHIKI KAISHA TOSHIBA, Tokyo (JP)

(72) Inventor: SHOICHI WATANABE, Yokkaichi Mie (JP)

(21) Appl. No.: 14/629,105

(22) Filed: Feb. 23, 2015

Related U.S. Application Data
(60) Provisional application No. 62/026,370, filed on Jul. 18, 2014.

(51) Int. Cl. G11C 16/08; H01L 27/092; H01L 21/8234; G11C 16/24; H01L 27/02; H01L 27/115

(52) U.S. Cl. CPC G11C 16/08; H01L 27/0288; H01L 27/11526; H01L 27/11573; H01L 21/823437; H01L 21/823475; G11C 16/24; H01L 27/092

(57) ABSTRACT

A semiconductor memory device includes a memory cell, a peripheral circuit configured to drive the memory cell, and a protection element. The peripheral circuit includes a first p-type MOS transistor including a gate electrode and a gate insulating film having a first film thickness, a second p-type MOS transistor including a gate electrode and a gate insulating film having a second film thickness, and an n-type MOS transistor. The gate electrode of the first p-type MOS transistor is connected to the protection element. The gate electrodes included in the second p-type MOS transistor and the n-type MOS transistor are connected only to an impurity region of another transistor or only to a gate electrode of the another transistor.

### CROSS-REFERENCE TO RELATED APPLICATION

This application is based upon and claims the benefit of priority from U.S. Provisional Patent Application No. 62/026,370, filed Jul. 18, 2014, the entire contents of which are incorporated herein by reference.

### FIELD

Embodiments described herein relate generally to a semiconductor memory device.

### BACKGROUND

In a NAND-type flash memory, the demand for high-reliability products has recently increased. The high-reliability products require not only reliability of the memory cells that store information in the flash memory device, but also reliability of the peripheral circuitry controlling the operation of the memory cells.

### BRIEF DESCRIPTION OF THE DRAWINGS

FIG. 1 is a schematic block diagram illustrating an electrical configuration of a NAND-type flash memory device.

FIG. 2 is a circuit diagram of a level shifter circuit of an address decoder.

FIG. 3A is a plan layout of a protection element and a high breakdown voltage p-type MOSFET which is present in a level shifter circuit of a row decoder unit of a NAND-type flash memory device according to a first embodiment, and FIG. 3B is a longitudinal sectional view taken along line 3-3 of FIG. 3A.

FIG. 4A is a plan layout diagram of a MOSFET other than the high breakdown voltage p-type MOSFET which is present in the level shifter circuit of the row decoder unit, and FIGS. 4B and 4C are longitudinal sectional view taken along line 4-4 of FIG. 4A.

FIG. 5A is a plan layout of a protection element and a high breakdown voltage p-type MOSFET which is present in a level shifter circuit of a row decoder unit of a NAND-type flash memory device according to a second embodiment, and FIG. 5B is a longitudinal sectional view taken along line 5-5 of FIG. 5A.

### DETAILED DESCRIPTION

In general, according to one embodiment, a semiconductor memory device includes a memory cell, a peripheral circuit configured to drive the memory cell, and a protection element. The peripheral circuit includes a first p-type MOS transistor including a gate electrode and a gate insulating film having a first film thickness, a second p-type MOS transistor including a gate electrode and a gate insulating film having a second film thickness, and an n-type MOS transistor. The gate electrode of the first p-type MOS transistor is connected to the protection element. The gate electrodes included in the second p-type MOS transistor and the n-type MOS transistor are connected only to an impurity region of another transistor or only to a gate electrode of the another transistor.

### First Embodiment

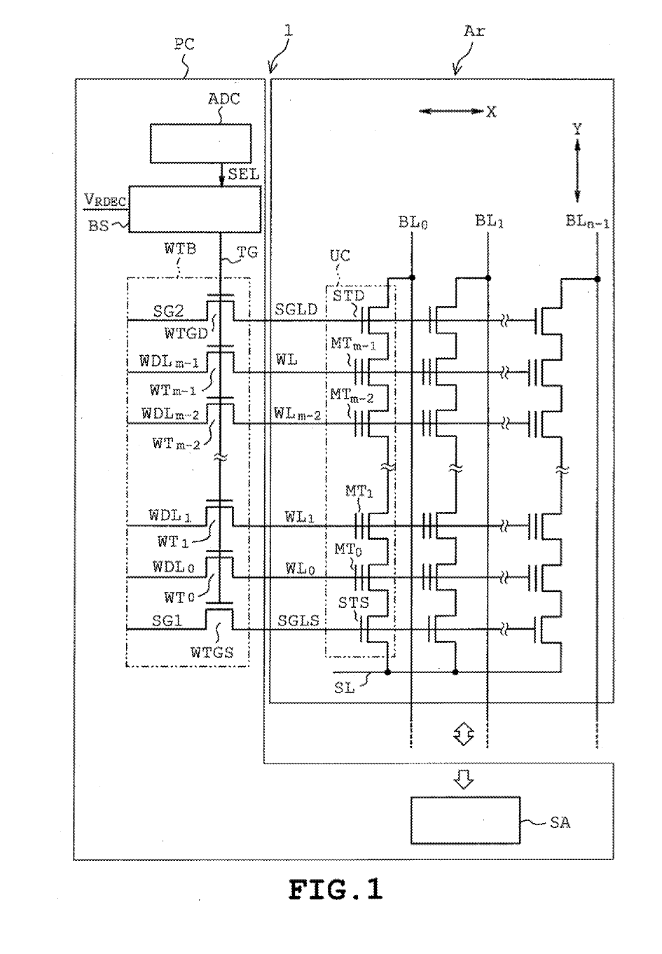

Hereinafter, a first embodiment of a NAND-type flash memory device as an example of a semiconductor memory device will be described with reference to FIGS. 1, 2, 3A, 3B, 4A, 4B, and 4C. In the following description, components having substantially the same function and configuration will be denoted by the same reference numerals and signs, and repeated description thereof will be appropriately omitted. The drawings schematically illustrate a NAND flash memory device, and the relationship between a thickness and a planar size thereof, a thickness ratio of each layer, and the like do not necessarily coincide with an actual device. In addition, terms indicating directions such as up and down in the description indicate relative directions when an element formation surface side of a semiconductor substrate to be described later is an upper side, and the directions may be different from actual directions on a device based on a gravitational acceleration direction.

Meanwhile, in the following description, an XYZ orthogonal coordinate system is used for convenience of description. In the coordinate system, two directions which are parallel to the surface of a semiconductor substrate and perpendicular to each other are selected as an X direction and a Y direction, a direction in which word lines WL extend is selected as the X direction, and a direction which is perpendicular to the X direction and in which bit lines BL extend is selected as the Y direction. A direction perpendicular to both the X direction and the Y direction is selected as the Z direction.

FIG. 1 is an example of a schematic block diagram illustrating an electrical configuration of a NAND-type flash memory device. As illustrated in FIG. 1, a NAND-type flash memory device 1 includes a memory cell array Ar in which a large number of memory cells are disposed in matrix form and a peripheral circuit PC configured to read, write, and erase the memory cells of the memory cell array Ar, and it includes an input and output interface circuit not illustrated in the drawing. The peripheral circuit PC drives or controls (reads, writes, and erases) the memory cells of the memory cell array Ar.

In the memory cell array Ar, a plurality of cell units UC are disposed. In each cell unit UC, for example, thirty-two memory cell transistors MT0 to MTm-1 are disposed between two selection gate transistors STD and STS, and are connected to each other in series. The selection gate transistor STD of each cell unit UC is connected to one of bit lines BL0 to BLn-1, and a selection gate transistor STS of each cell unit UC is connected to a source line SL.

In one block, n-rows of cell units UC are disposed in parallel to one another and are spaced apart in the X direction (row direction;) which is a first direction. In the memory cell array Ar, a plurality of blocks is disposed in the Y direction (column direction) which is a second direction. In addition, only one block is illustrated in FIG. 1 for the purpose of simplifying the description of the device.

A peripheral circuit region is provided at the periphery of the memory cell region, for example, a peripheral circuit PC is disposed at the periphery of the memory cell array Ar. The peripheral circuit PC includes an address decoder ADC, a sense amplifier SA (not shown), a booster circuit BS, a transfer transistor unit WTB, and the like. The address decoder ADC is electrically connected to the transfer transistor unit WTB through the booster circuit BS. The peripheral circuit PC includes a resistive element (not shown) as a peripheral circuit element.

The address decoder ADC selects one block B in response to an address signal applied from the outside of the peripheral circuit PC. The booster circuit BS is supplied with a driving voltage VRDEC from the outside of the address decoder ADC. Thus, when a selection signal SEL of the block B is applied, the booster circuit boosts the driving voltage VRDEC to thereby supply a predetermined voltage to transfer gate transistors WTGD, WIGS, and WT0 to WTm-1 through a transfer gate line TG.

The transfer transistor unit WTB includes a transfer gate transistor WTGD provided corresponding to the selection gate transistor STD, a transfer gate transistor WTGS provided corresponding to the selection gate transistor STS, and a plurality of word line transfer gate transistors WT0 to WTm-1 are provided to correspond to the respective memory cell transistors MT0 to MTm-1. A transfer transistor unit WTB is provided for each block B.

One of a drain and a source of the transfer gate transistor WTGD are connected to a selection gate driver line SG2, and the other of the drain and the source thereof is connected to a selection gate line SGLD. One of a drain and a source of the transfer gate transistor WIGS is connected to a selection gate driver line SG1, and the other of the drain and the source thereof is connected to a selection gate line SGLS. One of a drain and a source of each of the transfer gate transistors WT0 to WTm-1 is connected to each of the respective word line driving signal lines WDL0 to WDLm-1, and the other of the drains and the sources thereof are connected to each of the respective word lines WL0 to WLm-1 provided within the memory cell array Ar (memory cell region M).

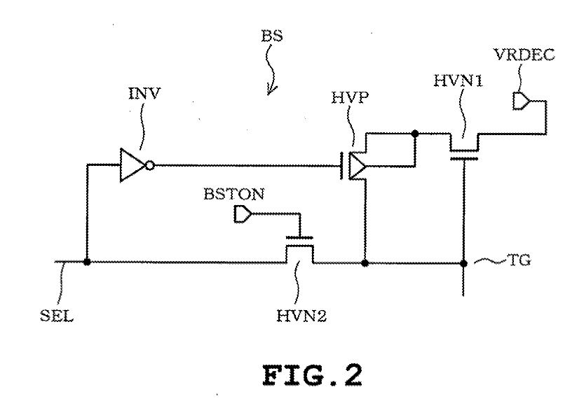

In the selection gate transistors STD of each of the plurality of cell units UC spaced in the X direction, the gate electrodes SG thereof are electrically connected to each other by the selection gate line SGLD. Similarly, in the selection gate transistors STS of the plurality of cell units UC spaced in the X direction, the gate electrodes SG thereof are electrically connected to each other by the selection gate line SGLS. Sources of the selection gate transistors STS are connected in common to the source line SL. Meanwhile, the selection gate transistors STD and STS will be referred to as selection gate transistors Trs in the description of FIG. 2 and the subsequent drawings.

In the memory cell transistors MT0 to MTm-1 of the plurality of cell units UC spaced in the X direction, the gate electrodes MG thereof are electrically connected to each other by the word lines WL0 to WLm-1.

In the transfer gate transistors WTGD, WIGS, and WT0 to WTm-1, the gate electrodes thereof are connected to each other in common by the transfer gate line TG and are connected to a boosting voltage supply terminal of the booster circuit BS. The sense amplifier SA is connected to each of the bit lines BL0 to BLn-1, and is connected to a latch circuit that temporarily stores data at the time of reading out the data.

FIG. 2 illustrates an example of a circuit diagram of a level shifter circuit of the address decoder ADC (row decoder). The level shifter circuit is equivalent to the booster circuit BS illustrated in FIG. 1. The booster circuit BS (level shifter circuit) includes an inverter INV, a high breakdown voltage p-type transistor HVP (p-type MOSFET 100 to be described later), a high breakdown voltage n-type transistor HVN1, and a high breakdown voltage n-type transistor HVN2.

The selection signal SEL is input to an input of the inverter and one of the source or drain of the high breakdown voltage n-type transistor HVN2. The driving voltage VRDEC (for example, approximately 25 V) is input to the source or drain of the high breakdown voltage n-type transistor HVN1. The other of the source and drain of the high breakdown voltage n-type transistor HVN1 is connected to the source or drain of the high breakdown voltage p-type transistor HVP. The other of the source and drain of the high breakdown voltage p-type transistor HVP, the other of the source and drain of the high breakdown voltage n-type transistor HVN2, and a control line of the high breakdown voltage n-type transistor HVN1 are connected in common to a node TG. A control line (gate electrode) of the high breakdown voltage p-type transistor HVP is connected to an output of the inverter INV. A signal BSTON is input to a control line (gate electrode) of the high breakdown voltage n-type transistor HVN2.

When the selection signal SEL is at a HIGH level (selection level), an output of the inverter INV is at a LOW level, and thus the high breakdown voltage p-type transistor HVP is turned on. In addition, when the signal BSTON is simultaneously at a HIGH level, the HIGH level is transmitted via the high breakdown voltage transistor HVN2 to the node TG, and thus the high breakdown voltage n-type transistor HVN1 is turned on.

As a result, the driving voltage VRDEC (approximately 25 V) is transmitted to the node TG through the high breakdown voltage n-type transistor HVN1 and the high breakdown voltage p-type transistor HVP. The p-type MOSFET 100 to be described later is used as the high breakdown voltage p-type transistor HVP mentioned above.

Incidentally, in the NAND-type flash memory device, the demand for high-reliability products has increased. The high-reliability products require not only reliability of memory cells that store information, but also reliability of the peripheral device for driving the memory cells.

In particular, one of reliability issue related to field effect MOS transistors (hereinafter, referred to as a metal-oxide-semiconductor field-effect transistor (MOSFET)) which configure a peripheral device (peripheral circuit) is negative bias temperature instability (NBTI). NBTI refers to a phenomenon in which a threshold voltage Vth, an on current Ion, and an off current Ioff fluctuate (are shifted) in association with an increase in an application time when a negative voltage is applied to a gate electrode of the MOSFET, that is, a degradation phenomenon in negative bias temperature stress. The NBTI is a phenomenon which is present, particularly, in a p-type MOSFET.

The factors of degradation (an increase of the threshold voltage Vth, and changes to the on current Ion, and the off current Ioff) due to the NBTI phenomenon cause an increase in an interface level and an increase in positive charge in the gate insulating film. Damage due to ion bombardment during plasma etching of the film layers of the device is known as one of the factors causing an increase in degradation due to the NBTI phenomenon. In a general manufacturing process of a semiconductor device, for example, in a process of forming a groove for forming a wiring layer, a plasma based dry etching process may be used. In this process, the charged particles (ions) generated in the plasma infiltrate into gate electrodes of the MOSFET connected to a wiring layer and a contact at the lower layer thereof via the wiring layer and the contact. The charge is accumulated in the gate electrode, and thus damage (hereinafter, referred to as process damage) may occur to or in the gate insulating film located below the gate electrode.

There is a tendency for an interface level and charge to increase in the gate insulating film as a result of the plasma induced process damage, and thus operating characteristics such as the threshold voltage Vth, the on current Ion, and the off current Ioff of the MOSFET fluctuate from memory cell to memory cell and from device to device. That is, transistor characteristics are degraded due to the NBTI phenomenon. The process damage is proportional to a value (referred to as an antenna ratio) which is obtained by dividing a surface area of a conductor exposed to plasma by an area (in this case, an area of the gate electrode) of a location, which will be damaged.

In order to suppress the NBTI induced degradation of the MOSFET and to increase the reliability of a device, it is important to reduce plasma induced processing damage.

By connecting a capacitive electrode of a capacitive element in parallel to a gate electrode, it is possible to increase an effective gate area (capacitance value) which absorbs process damage (the amount of charge of charged particles) and reduces the antenna ratio. That is, it is possible to disperse process damage (the quantity of charge resulting from charged species in the plasma) by the connected capacitive element. Accordingly, it is possible to reduce plasma induced processing damage if this configuration is formed. However, since the capacitive element does not allow charge to escape, the reduction in plasma induced processing damage to the MOSFET depends on the size of the area of the capacitive electrode of the capacitive element.

Additionally, the provision of the capacitive element leads to an increase in chip area of a device, i.e., it increases device size and reduces the number of devices which can be formed on a substrate. In addition, since wiring for connecting the elements is already laid out or established for the device, the degree of freedom of the routing (layout) of the wiring for the capacitive element is limited. Further, since the total capacitance is increased from the viewpoint of an electrical characteristic, the total capacitance connected to the MOSFET is increased, and thus the RC delay is increased. Therefore, the operating speed of the circuit including the MOSFET and additional capacitor is decreased.

The level shifter circuit of the row decoder unit mentioned above is one of peripheral circuits requiring reliability. The level shifter circuit is a circuit for transmitting a voltage of a power line to a word line at the time of writing, and is required to operate normally for a warranted number of writings of a NAND-type flash memory. As the reliability requirement for NAND-type flash memories increases, it is important to secure sufficient reliability of the level shifter circuit. An n-type MOSFET and a p-type MOSFET which include a thick gate insulating film for a high breakdown voltage are normally used for the circuit so that the circuit is capable of withstanding a high voltage. Among these, the p-type MOSFET is susceptible to NBTI. Therefore, the improvement in the NBTI of the p-type MOSFET leads to an improvement in the reliability of the level shifter circuit.

The level shifter circuit is operated at a lower speed as compared with other circuits. Thus, even when an operational delay due to the connection of the capacitive element occurs, the influence of this slower operational speed on the entire device is small. Therefore, even when the reliability of the device is improved by connecting a MOS type capacitive element to the p-type MOSFET as a protection element, it is possible to satisfy the operational speed requirements of the device.

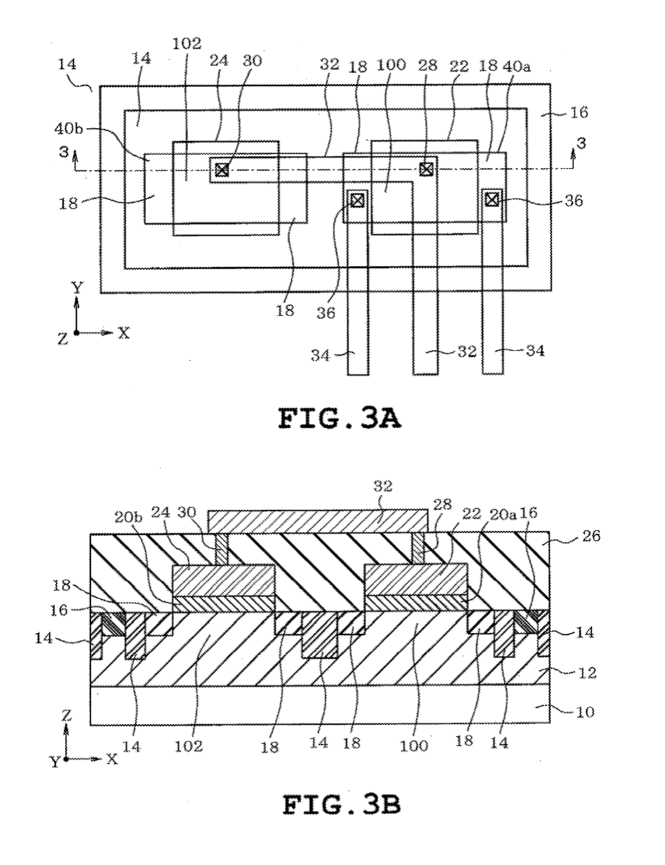

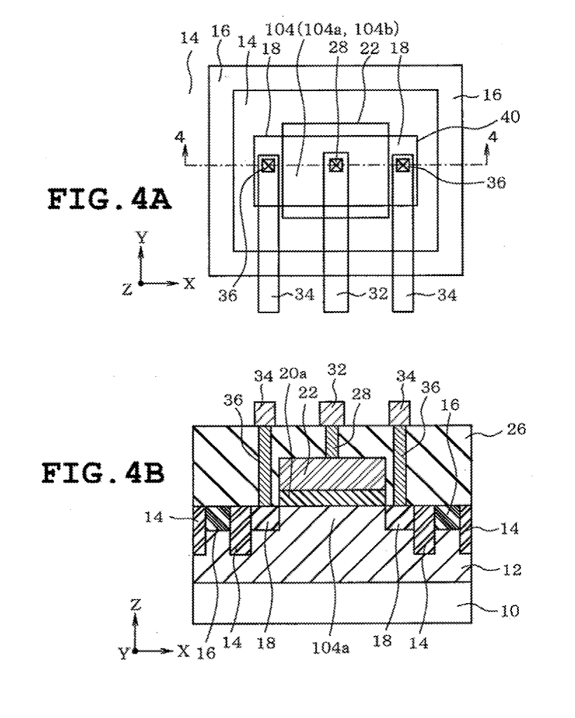

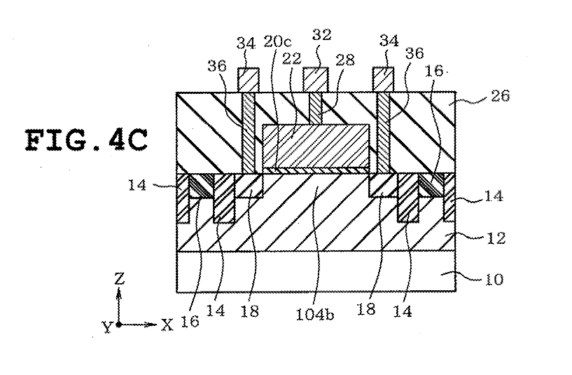

FIGS. 3A, 3B, 4A, 4B, and 4C illustrate an example of a configuration of a portion of the peripheral circuit according to the first embodiment. FIG. 3A schematically illustrates an example of a planar layout of a protection element 102 of an NBTI which protects the p-type MOSFET and the p-type MOSFET 100 which is present in the level shifter circuit of the row decoder unit of the NAND-type flash memory device according to the first embodiment. FIG. 3B illustrates an example of a longitudinal sectional view taken along line 3-3 of FIG. 3A.

As illustrated in FIGS. 3A and 3B, the p-type MOSFET 100 includes an element region 40a of a semiconductor substrate 10 (FIG. 3B). For example, a silicon substrate may be used as the semiconductor substrate 10. The element region 40a is formed on the surface of the semiconductor substrate 10. Here, the p-type MOSFET 100 which is present in the level shifter circuit of the row decoder unit is a high breakdown voltage (HV) p-type MOSFET.

A well 12 is formed within the semiconductor substrate 10 by introducing n-type impurities such as, for example, phosphorus (P) by ion implantation methods to form the well 12. A gate electrode 22 is provided on a gate insulating film 20a formed on the element region 40a. The gate insulating film 20a is formed of, for example, a silicon oxide film (SiO₂), and is formed to have a large thickness so that the p-type MOSFET 100 functions as a high breakdown voltage transistor.

The gate electrode 22 is formed of, for example, polysilicon, metal, or a laminated film thereof. A doped region 18 is formed in the element region 40a at both sides of the gate electrode 22. The doped regions 18 function as the source and drain regions of the p-type MOSFET 100. The doped regions 18 are connected to a wiring 34 through a contact 36. The gate electrode 22 is connected to a wiring 32 through a contact 28. The contact 28 and the wiring 32 are formed of a metal such as, for example, tungsten (W). The contact 28 may have a barrier metal formed thereover (between the W and the silicon), for example, a titanium (Ti) and titanium nitride (TiN) barrier layer, or both.

The protection element 102 includes an element region 40b on the semiconductor substrate 10, on which a MOS insulating film 20b is formed. An electrode 24 is provided over the element region 40b (semiconductor substrate 10) on the MOS insulating film 20b. That is, the protection element 102 is a MOS capacitive element having a MOS-type structure. The MOS insulating film 20b is formed to have a film thickness the same as a thickness of the gate insulating film 20a of the p-type MOSFET 100 and is formed of the same material (silicon oxide film) as that of the gate insulating film 20a, such that they may be formed simultaneously during manufacturing of the NAND flash memory. The electrode 24 has the same structure as that of the gate electrode 22 of the p-type MOSFET 100 such that they may also be formed simultaneously during manufacturing of the NAND flash memory. An element region 40b located at either side of the electrode 24 includes the doped region 18. The doped region 18 of the protection element 102 may not need to be provided. The electrode 24 is connected to the wiring 32 through a contact 30. The wiring 32 connects the gate electrode 22 and the electrode 24. The contact 30 has the same structure as that of the contact 28 and is formed of the same material as that of the contact 28 such that they may also be formed simultaneously during manufacturing of the NAND flash memory.

Each of the element regions 40a and 40b are surrounded by an element isolation area 14. For example, the element isolation area 14 is formed by embedding a silicon oxide film within a groove formed in the semiconductor substrate 10. The outside perimeter of the element isolation area 14 is surrounded by a well contact region 16. That is, the p-type MOSFET 100 and the protection element 102 are surrounded by the well contact region 16. The outside of the well contact region 16 is surrounded by an additional element isolation area 14 (FIG. 3b). N-type impurities such as, for example, phosphorus are introduced into the well contact region 16 such as by ion implantation. A well contact (not illustrated in the drawing) is connected to the well contact region 16, and thus it is possible to apply a predetermined potential to the well 12. The well contact region 16 also functions as a guard ring that prevents noise in the device.

As described above, the gate electrode 22 of the p-type MOSFET 100 which is present in the level shifter circuit of the row decoder unit is connected to the electrode 24 of the protection element 102 through the wiring 32. Thus, for example, when plasma induced process damage (the amount of charge of charged particles) is applied to the gate electrode 22 of the p-type MOSFET 100 through the wiring 32, the gate electrode 22 is connected to the electrode 24 of the protection element 102 through the wiring 32, and thus the ions otherwise causing process damage are dispersed to the protection element.

That is, it is possible to disperse the ions causing process damage by the connection of the protection element 102, as compared with a case where the gate electrode 22 is not connected to the electrode 24. Thus, process damage to the gate insulating film 20a located under the gate electrode 22 is reduced, and thus NBIT based degradation of the p-type MOSFET 100 is suppressed. Therefore, the protection element 102 is connected to the p-type MOSFET 100 of the level shifter circuit of the row decoder unit, and thus it is possible to reduce NBTI degradation of a NAND-type flash memory device while minimizing the reduction in the operational speed thereof due to an RC delay and to improve the reliability of the entire device.

FIGS. 4A, 4B, and 4C are schematic diagrams illustrating an example of a configuration of a MOSFET 104, other than the p-type MOSFET 100, which is present in a peripheral circuit region of a NAND-type flash memory device to which the first embodiment is applied. The MOSFET 104 is a MOSFET which is used in, for example, a logic circuit. As the MOSFET 104, a high breakdown voltage (HV) p-type MOSFET 104a and a low breakdown voltage (LV) p-type MOSFET 104b are illustrated as representatives. A description will be made on the assumption that the illustrated layouts thereof are the same. Here, a p-type MOSFET is illustrated as the MOSFET 104, but the MOSFET 104 may be an n-type MOSFET. In this case, a p-type dopant which is a conductive type of each of the high breakdown voltage (HV) p-type MOSFET 104a and the low breakdown voltage (LV) p-type MOSFET 104b, which are mentioned above, may be replaced with an n-type dopant.

FIG. 4A schematically illustrates a layout diagram of the MOSFET 104. FIGS. 4B and 4C schematically illustrate a longitudinal sectional view taken along line 4-4 of FIG. 4A. FIG. 4B illustrates a longitudinal sectional view of the high breakdown voltage (HV) p-type MOSFET 104a, and FIG. 4C illustrates a longitudinal sectional view of the low breakdown voltage (LV) p-type MOSFET 104b. The gate insulating film 20c of the low breakdown voltage p-type MOSFET 104b has a film thickness which is smaller than the film thickness of the gate insulating film 20a of the high breakdown voltage p-type MOSFET 104a. The gate insulating film 20c of the low breakdown voltage p-type MOSFET 104b has a film thickness which is smaller than a film thickness of the gate insulating film 20a of the p-type MOSFET 100. The gate insulating film 20c of the low breakdown voltage p-type MOSFET 104b also has a film thickness which is smaller than a film thickness of the MOS insulating film 20b of the protection element 102.

As illustrated in FIGS. 4B and 4C, the gate electrodes 22 of the high breakdown voltage p-type MOSFET 104a and of the low breakdown voltage p-type MOSFET 104b are not connected to the electrode 24 of the protection element 102. The gate electrode 22 of the low breakdown voltage p-type MOSFET 104b is connected to only a doped region (source or drain) of another transistor or only a gate electrode of another transistor through wiring 32. For example, the gate electrode of the p-type MOSFET 100 (HVP in FIG. 2) which is used in the level shifter circuit of the row decoder unit illustrated in FIG. 2B is connected to an output of the inverter INV. When the inverter INV is configured with a CMOS circuit, the gate electrode of the p-type MOSFET 100 is connected to impurity regions (a source and drain region and a diffusion layer region) of a MOSFET configuring the CMOS circuit.

In this manner, the gate electrode 22 of the MOSFET 104 (a p-type MOSFET and an n-type MOSFET are included) other than the p-type MOSFET 100 which is present in the level shifter circuit of the row decoder unit of the peripheral circuit unit is not connected to the electrode 24 of the protection element 102. Thus, any RC delay due to the connection of the protection element 102 does not occur in the MOSFET 104 other than in the high breakdown voltage p-type MOSFET 100 which is present in the level shifter circuit of the row decoder unit.

That is, according to this embodiment, it is possible to improve the reliability of the device by connecting the protection element 102 to the p-type MOSFET 100, and the operational speed of the circuit having the MOSFET 104 other than the p-type MOSFET 100 is not impaired. Therefore, it is possible to satisfy the requirements of the operational speed of the entire device while improving the reliability of the entire device.

### Second Embodiment

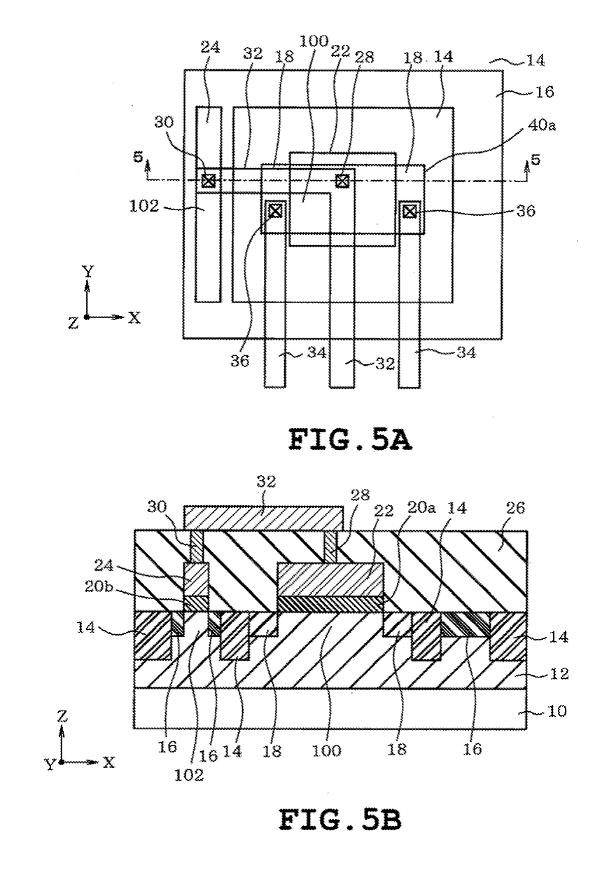

FIGS. 5A and 5B illustrate a configuration of a portion of a peripheral circuit according to a second embodiment. FIG. 5A schematically illustrates a layout of a protection element 102 and a high breakdown voltage p-type MOSFET 100 which is present in a level shifter circuit of a row decoder unit of a peripheral circuit of a NAND-type flash memory device according to the second embodiment. FIG. 5B illustrates a longitudinal sectional view taken along line 5-5 of FIG. 5A.

The second embodiment is different from the first embodiment in that a location where the protection element 102 is formed is different. That is, in the second embodiment, the protection element 102 is formed in a well contact region 16. The protection element 102 is disposed in the above-mentioned manner, and thus it is possible to form the protection element 102 without increasing the layout area for forming the protection element 102. In addition, it is possible to exhibit the same effects as those in the first embodiment with the above-mentioned configuration.

### Other Embodiments

Although an example in which a NAND-type flash memory device has been described, the disclosure may be applied to a NOR-type flash memory device, a non-volatile semiconductor memory device such as an EPROM, a semiconductor memory device such as a DRAM or an SRAM, or a logic semiconductor device such as a microcomputer.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the disclosure.

What is claimed is:

1. A semiconductor memory device comprising:
a memory cell;
a peripheral circuit configured to drive the memory cell; and
a protection element,
wherein the peripheral circuit includes a first p-type MOS transistor including a gate electrode and a gate insulating film having a first film thickness, a second p-type MOS transistor including a gate electrode and a gate insulating film having a second film thickness, and an n-type MOS transistor,
wherein the gate electrode of the first p-type MOS transistor is connected to the protection element, and
wherein the gate electrodes included in the second p-type MOS transistor and the n-type MOS transistor are connected only to an impurity region of another transistor or only to a gate electrode of the another transistor.

2. The semiconductor memory device according to claim 1, wherein the first p-type MOS transistor is a level shifter circuit of a row decoder unit.

3. The semiconductor memory device according to claim 1, wherein the first film thickness is larger than the second film thickness.

4. The semiconductor memory device according to claim 1, further comprising:
a well contact region,
wherein the protection element is disposed in the well contact region.

5. The semiconductor memory device according to claim 1, wherein the protection element has a MOS-type structure including a MOS insulating film.

6. The semiconductor memory device according to claim 5, wherein the MOS insulating film has the same film thickness as the film thickness of the gate insulating film included in the first p-type MOS transistor.

7. The semiconductor memory device according to claim 4, wherein the well contact region surrounds the first p-type MOS transistor.

8. The semiconductor memory device according to claim 4, wherein the well contact region surrounds the first p-type MOS transistor and the protection element.

9. The semiconductor memory device according to claim 1, wherein the protection element is a capacitor.

10. A semiconductor memory device comprising:
a memory cell;
a peripheral circuit configured to drive the memory cell; and
a protection element,
wherein the peripheral circuit comprises a first p-type MOS transistor including a gate electrode and a gate insulating film having a first film thickness, a second p-type MOS transistor including a gate electrode and a gate insulating film having a second film thickness, and an n-type MOS transistor,
wherein the gate electrode included in the first p-type MOS transistor is connected to the protection element, and
wherein the gate electrodes included in the second p-type MOS transistor and in the n-type MOS transistor are not connected to the protection element.

11. The semiconductor memory device according to claim 10, wherein the first p-type MOS transistor is in a level shifter circuit of a row decoder unit.

12. The semiconductor memory device according to claim 10, wherein the first film thickness is larger than the second film thickness.

13. The semiconductor memory device according to claim 10, further comprising:
a well contact region,
wherein the protection element is disposed in the well contact region.

14. The semiconductor memory device according to claim 10, wherein the protection element has a MOS-type structure including a MOS insulating film.

15. The semiconductor memory device according to claim 14, wherein the MOS insulating film has the same film thickness as the film thickness of the gate insulating film of the first p-type MOS transistor.

16. The semiconductor memory device according to claim 13, wherein the well contact region surrounds the first p-type MOS transistor.

17. The semiconductor memory device according to claim 13, wherein the well contact region surrounds the first p-type MOS transistor and the protection element.

18. The semiconductor memory device according to claim 13, wherein the protection element is formed on the well contact region.

19. A method of protecting a semiconductor device from negative-bias temperature instability, comprising:
providing a peripheral circuit comprising a first p-type MOS transistor including a gate electrode on a gate insulating film having a first film thickness, a second p-type MOS transistor including a gate electrode on a gate insulating film having a second film thickness, and an n-type MOS transistor; and
connecting the gate electrode of the first p-type MOS transistor to a protection element and not connecting the gate electrodes included in the second p-type MOS transistor and in the n-type MOS transistor to the protection element.

20. The method of claim 19, further comprising:
forming the gate electrode of the first p-type MOS transistor and an electrode of the protective element on the gate insulating film having the first film thickness.
